(19) United States
(12) Patent Application Publication
(10) Pub. No.: US 2007/0076389 A1
(43) Pub. Date: Apr. 5, 2007

(54) Electronic device with conductive connection structure

(75) Inventors: Chih-Yuan Wang, Taichung County (TW); Heng-Yi Chang, Taipei City (TW); Ya-Ling Hsu, Changhua County (TW)

Correspondence Address: BACON & THOMAS, PLLC, 625 SLATERS LANE, FOURTH FLOOR, ALEXANDRIA, VA, 22314, US

(73) Assignee: Wintek Corporation, Taichung (TW)

(21) Appl. No.: 11/339,697

(22) Filed: Jan. 26, 2006

(30) Foreign Application Priority Data
Sep. 2, 2005 (TW) 94130215

(51) Int. Cl. H05K 7/00

(52) U.S. Cl. 361/760

(57) ABSTRACT

The present invention provides an electronic device with a conductive connection structure, which has a substrate with conductive media thereon. The conductive media are electrically connected to conductive saliences respectively. These saliences are electrically connected to other electronic devices directly or indirectly. Each of the saliences has a space therein and at least a hollow portion communicated with the space. The spaces provide the saliences with a capacity of deformation. Glue can be filled in the spaces to reinforce the bonding strength.

### BACKGROUND OF THE INVENTION

1. Field of the Invention

The present invention relates generally to a conductive connection structure, and more particularly to an electronic device with a conductive connection structure for conductive connection between an integrated circuit device and a substrate of an optical display.

2. Description of the Related Art

FIG. 1 shows a conductive connection structure of an integrated circuit device 1 and a glass substrate 2. The integrated circuit device 1 is provided with bump pads 1a on a side thereof, on each of which a gold bump 3 is provided respectively. The glass substrate 2 has conductive films 2a to be bonded to the integrated circuit device 1 by an anisotropic conductive film 4. The anisotropic conductive film 4 has conductive particles 4a to conduct electricity between the gold bumps 3 and the conductive films 2a. Because a thermal expansion coefficient of the conductive film 4 is greater than that of the gold bumps 3, so that there will be damage or crack on a conductive connection portion by the stress produced in the condition when they are bonded in a high-temperature and cooled to a room-temperature to cause the change in sizes. Therefore, the electric conduction is getting poor or causes open. In addition, the gold bumps 3 are not hollow elements so that the conductive films 2a is damaged when exert a greater pressure on it.

FIG. 2 is another conductive connection structure, which an integrated circuit device 5 has bump pads 5a and composite bumps 6 on the bump pads 5a. Each of the bumps 6 has a macromolecular elastic member 6a and a conductive metallic film 6b covering the entire elastic member 6a. To bond the integrated circuit device 5 and a glass substrate 7, the bumps 6 will be deformed to increase the area for conduction. However, the metallic films 6b of the bumps 6 is supported by the elastic member 6a, so that the pressure for bonding must be greater than the damping counter force of the elastic member 6a to make the metallic films 6b having the greater area to be in touch of a conductive film 7a on a surface of the substrate 7 (referring to FIG. 3). However, the thinner metallic films 6b will be damaged because of the greater pressure for bonding to cause a bad condition of conduction.

### SUMMARY OF THE INVENTION

The primary objective of the present invention is to provide an electronic device with a conductive connection structure, which has a chamber therein with a conductive salience for electric conduction. The conductive salience has a well electric conduction.

According to the objective of the present invention, the present invention provides an electronic device with a conductive connection structure, which has a substrate with conductive media thereon. The conductive media are electrically connected to conductive saliences respectively. These saliences are electrically connected to other electronic devices directly or indirectly. Each of the saliences has a space therein and at least a hollow portion communicated with the space.

### BRIEF DESCRIPTION OF THE DRAWINGS

FIG. 1 is a sectional view of the conventional conductive connection structure of the integrated circuit device and the glass substrate;

FIG. 2 and FIG. 3 are sectional views of another conventional conductive connection structure of the integrated circuit device and the glass substrate;

FIG. 4 is a perspective view in part of the electronic device of a first preferred embodiment of the present invention;

FIG. 5 is a lateral view of the electronic device of the first preferred embodiment of the present invention;

FIG. 6 is a sectional view of electric connection of the electronic device and the integrated circuit unit of the first preferred embodiment of the present invention;

FIG. 7 shows the deformation of the salience of FIG. 6;

FIG. 8 shows the damage of the salience of FIG. 6;

FIG. 9 is similar to FIG. 4, showing the salience with a waved top portion;

FIG. 10 is similar to FIG. 4, showing the salience with a saw-toothed top portion;

FIG. 11 is similar to FIG. 7, showing the adhesive media using non-conductive film;

FIG. 12 is a sectional view of electric connection of the electronic device and the integrated circuit unit of a second preferred embodiment of the present invention;

FIG. 13 shows the deformation of the salience of the electric device of the second preferred embodiment of the present invention;

FIG. 14 is a sectional view of an application of the present invention, showing two electronic devices with the saliences to be connected by the conductive film;

FIG. 15 is similar to FIG. 14, showing the non-conductive film used to bond the electronic devices;

FIG. 16 is similar to FIG. 4, showing the salience having three lateral portions;

FIG. 17 is similar to FIG. 4, showing the salience having four lateral portions;

FIG. 18 shows the V-shaped salience of the present invention;

FIG. 19 shows the V-shaped salience of the present invention connected to another electronic device; and

FIG. 20A to FIG. 20L are flow diagrams, showing how to make the salience of the present invention.

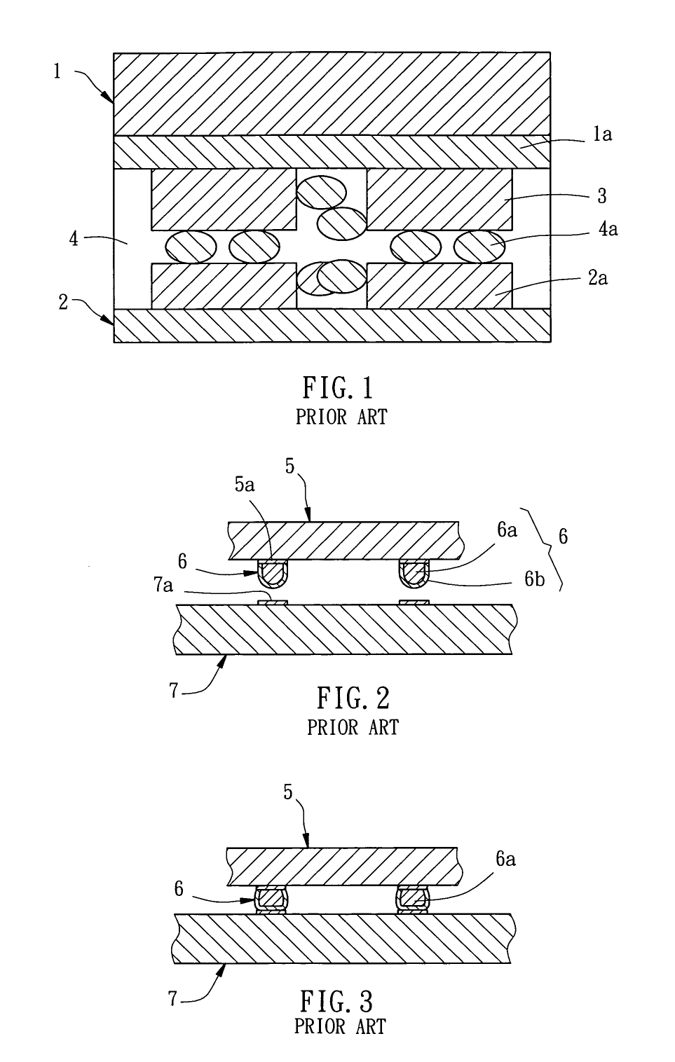

### DETAILED DESCRIPTION OF THE INVENTION

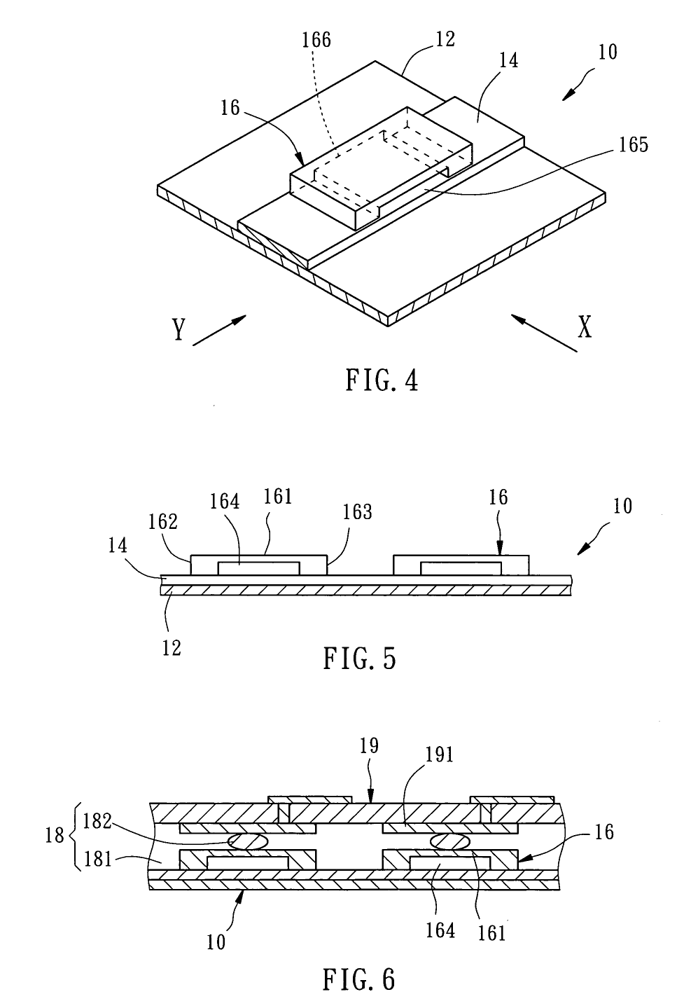

As shown in FIGS. 4 and FIG. 5, an electronic device 10 with a conductive connection structure includes a substrate 12, a plurality of conductive media 14 and conductive saliences 16.

The substrate 12 is a glass substrate of an element of an optical display panel.

The conductive media 14 are conductive films, which have predetermined loci, on a surface of the substrate 12.

The saliences 16 are provided on a surface of the conductive media 14 respectively, each of which is a rectangular member with a top portion 161, and a first lateral portion 162 and a second lateral portion 163 to support the top portion 161. As shown in FIG. 4, the top portions 161 of the saliences 16 have a height difference to the relative conductive media 14 respectively. The top portion 161, the first lateral portion 162, and the second lateral portion 163 of the saliences 16 and the conductive media 14 enclose a space 164. A first hollow portion 165 and a second hollow portion 166 are formed between a front side and a rear side of the first lateral portion 162 and the second lateral portion 163 and are communicated with the space 164. The saliences 16 are like an inverted U-shaped bridge from a X direction (referring to FIG. 5). In addition, the top portions 161 of the saliences 16 of the present invention have thicknesses in a range between 10 Å and 100,000 Å. The saliences 16 are made of gold, silver, copper, nickel, aluminum, their alloy or the like, and that is why the saliences 16 conducting electricity. The saliences 16 are preferred made of copper or nickel.

Above are the descriptions of the structure of the electronic device 10 of the first preferred embodiment of the present invention, and hereunder will describe the applications.

As shown in FIG. 6, the electronic device 10 of the first preferred embodiment of the present invention is electrically connected to an integrated circuit unit 19 via an anisotropic conductive film 18. In the process of pressing the electronic device 10 and the integrated circuit unit 19 together, conductive particles 182 in an adhesive layer 181 of the conductive film 18 touch the saliences 16 of the electronic device 10 and bump pads 191 of the integrated circuit unit 19 in the same time to conduct the electronic device 10 to the integrated circuit unit 19.

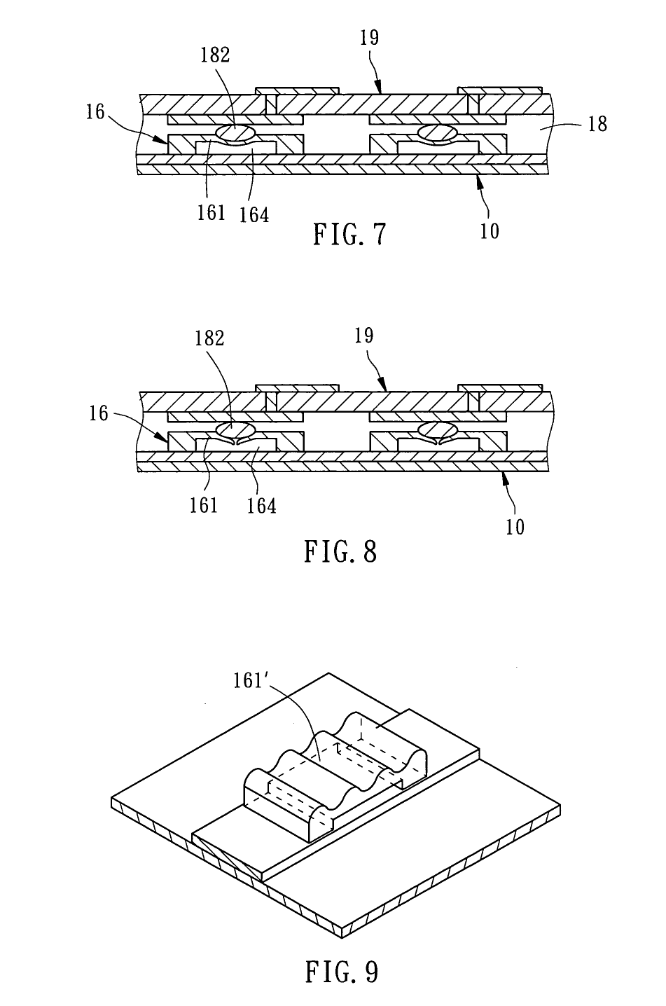

FIG. 7 shows the deformation of the top portion 161 of the salience 16 when it is pressed by the conductive particles 182. The conductive particles 182 are deformed or broken also. Therefore, it makes the conductive particles 182 have more area to touch the top portion 161 of the salience 16. The deformed saliences 16 absorb the pressure to avoid damage. The facts of making the top portions 161 concaved includes the strength of the pressure, the material made of the saliences 16, and most of all, each of the saliences 16 has the space 164. When the conductive particles 182 press the top portion 161, there is no any resistance under the top portion 161, so that the top portion 161 is deformed freely. As a result, the conductive particles 182 are rested the top portion 161 with an inlaid condition to increase the area for conduction that makes a well electric conduction.

Even when the top portions 161 of the saliences 16 are broken by the pressure, as shown in FIG. 8, the broken top portions 161 provide more area for conduction. In addition, the broken top portions 161 have a further function of holding the conductive particles 182 to prevent them from movement. Therefore, when the top portions 161 are broken in the process of pressing, they will not affect the conduct electricity.

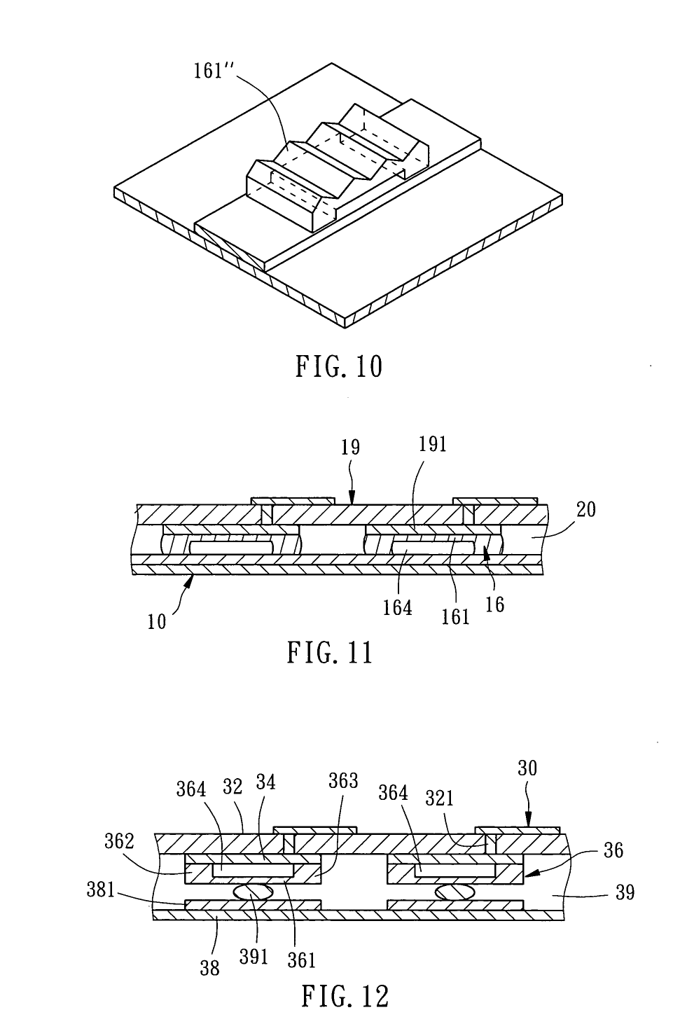

In addition, the top portions 161 of the saliences 16 of the present invention can be made to have a rough surface that can increase the area for conduction. FIG. 9 shows a top portion 161′ having a waved surface, and FIG. 10 shows a top portion 161″ having a saw-toothed surface.

In above preferred embodiments, the conductive film 18 with conductive particles 182 is used to attach the electronic device 10 on the integrated circuit unit 19. However, except the conductive film 18, a non-conductive film (NCF) 20 can be used as adhesion media. As shown in FIG. 11, the electronic device 10 has the top portions 161 of the saliences 16 touching the bump pads 191 of the integrated circuit unit 19 directly for electrical conduction.

It has to be mentioned that the saliences 16 of the present invention have the spaces 164, so that the spaces 164 will be filled with the conductive film 18 or the non-conductive film 20 via the first and second hollow portions 165, 166 in the process of bonding the electronic device 10 and the integrated circuit unit 19. It helps the electronic device 10 and the integrated circuit unit 19 bonded together firmly. In the meantime, gas will be exhausted via the first and second hollow portions 165, 166 when the saliences 16 are deformed.

FIG. 12 shows the second preferred embodiment of the present invention, which an electronic device 30 is electrically connected to a glass substrate 38 of a display via a conductive film 39. The electronic device 30 has a substrate 32, conductive media 34 and conductive saliences 36, and the differences are:

The substrate 32 of the electronic device 30 of the second preferred embodiment of the present invention is an integrated circuit member with traces 321 therein. The substrate 32 has bump pads for input and output to form the conductive media 34. The saliences 36 are on the surfaces of the conductive media 34 respectively, which are the bridge-like structures as same as the electronic device of the first preferred embodiment, in other word, each of the saliences 36 has a top portion 361, a first lateral portion 362 and a second lateral portion 363 supporting the top portion 361, and a space within the top portion 361, the first lateral portion 362, the second lateral portion 363, and the conductive media 34. The space 364 is open at two sides.

The glass substrate 38 has conductive films 381 on a surface thereof. In the process of bonding the electronic device 30 and the glass substrate 38, the conductive film 39 has conductive particles 391 electrically connecting the saliences 36 of the electronic device 30 and the conductive films 381 of the glass substrate 38. The spaces 364 are filled with a glue of the conductive film 39 to increase the bonding strength of the electronic device 30 and the glass substrate 38. Of course, a non-conductive film may be used to be the adhesion medium of the electronic device 30 and the glass substrate 38, and the saliences 36 touches the conductive films 381 directly.

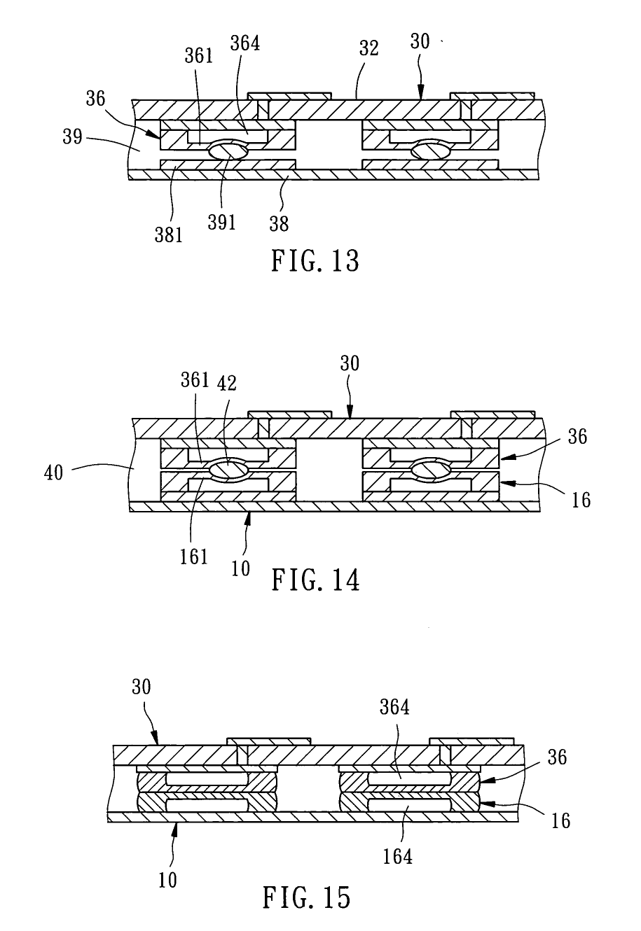

FIG. 13 shows the deformation of the top portions 361 of the saliences 36 that produces more area to touch the conductive particles 391. We have described the reason of making the top portions 361 deformed in FIG. 7. In the same way, the saliences of the present preferred embodiment may be broken, and the top portions 361 of the saliences 36 may have a rough surface like FIG. 9 and FIG. 10. These equivalent embodiments are described above, and we will not describe them again.

FIG. 14 shows an application of the present invention, in which the electronic device 10 of the first preferred embodiment is bonded to the electronic device 30 of the second preferred embodiment via a conductive film 40. The top portions 161 of the saliences 16 of the electronic device 10 are electrically connected to the top portions 361 of the saliences 36 of the electronic device 30 via the conductive particles 42 of the conductive film 40. The top portions 161 and 361 may be deformed to increase the area for electric conduction and to increase the conduction efficiency. In FIG. 15, it shows a non-conductive film 30 used to bond the electronic devices 10 and 30. The saliences 16 and 36 are in touch with each other directly and are deformed to electrically conduct the electronic devices 10 and 30.

The equivalent structures of the saliences of the present invention are described hereunder:

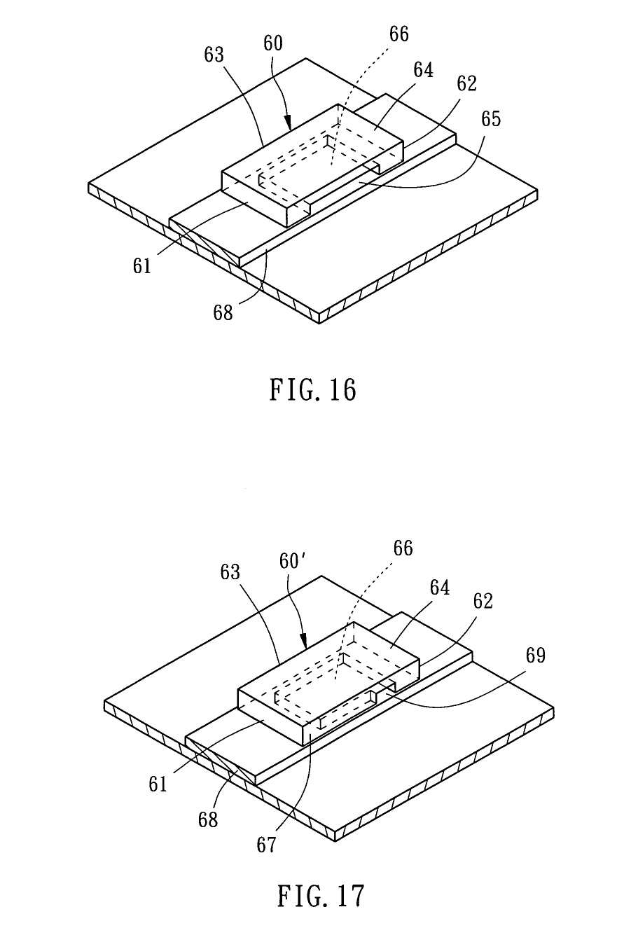

FIG. 16 shows a salience 60 including a first lateral portion 61, a second lateral portion 62, a third lateral portion 63, and a top portion 64. The third lateral portion 63 has two ends connected to the first lateral portion 61 and the second lateral portion 62 respectively so that the salience 60 has a hollow portion 65 at a side opposite to the third lateral portion 63. All of the lateral portions 61, 62 and 63 support the top portion 64. The lateral portions 61, 62 and 63 and a conductive medium 68 enclose a space 66, and the space 66 is communicated with the hollow portion 65. Because the saliences are very fine structures, the spaces 66 provide the saliences 60 deformed without any resistance when they are exerted by external force. The spaces 66 also allow glue filled therein via the hollow portions 65 to reinforce the bonding strength and to exhaust gas in the spaces 66 out via the hollow portions 65 when the saliences 60 are deformed.

FIG. 17 shows a salience 60′ following the salience 60 of FIG. 16, which has a fourth lateral portion 67 at a side opposite to the third lateral portion 63. The fourth lateral portion 67 is connected to the top portion 64, the first lateral portion 61, and the conductive media 68 and keeps a distance from the second lateral portion 62 to form a hollow portion 69. The hollow portion 69 allows gas escaping when the salience 60′ is deformed.

The saliences described above are rectangular members. Any shape of the salience with the top portion, the space, and at least a lateral portion is an equivalent structure of the present invention, and it is within the scope of the present invention.

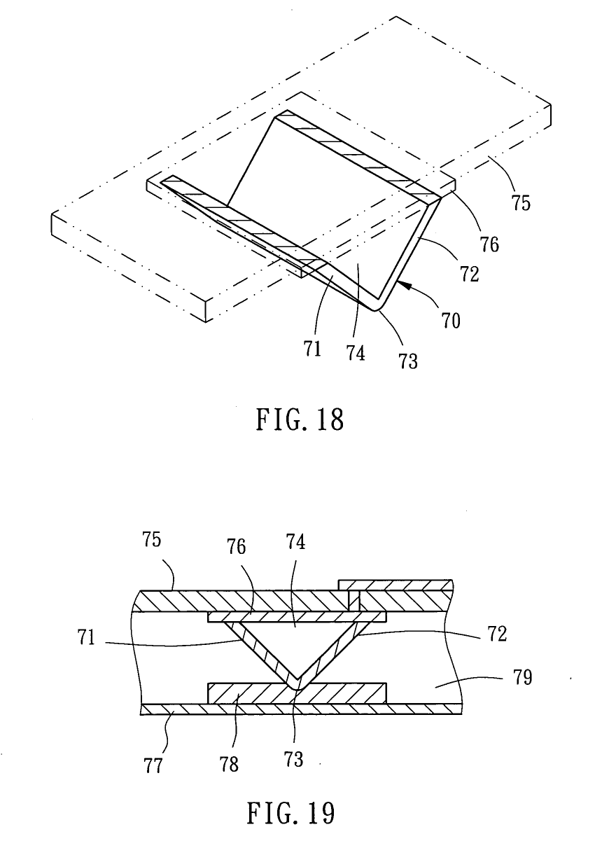

The character of the salience of the present invention is that it has the space and at least a hollow portion to take the deformation of the salience and to fill glue therein to reinforce the bonding strength. In addition to the saliences as described above, it can be made like FIG. 18. The salience 70 of FIG. 18 is mounted on bump pads 76 of an integrated circuit device 75. The salience 70 has a first inclining portion 71, a second inclining portion 72, a touching portion 73 connected to tops of the first inclining portion 71 and the second inclining portion 72, and a space 74 within the first inclining portion 71, the second inclining portion 72, and the bump pads 76. The space 74 is open at two sides. FIG. 19 shows a salience 70 having a pointed touching portion 73 to be inserted into a conductive film 78 on a surface of a glass substrate 77 for electric conduction. A non-conductive film 79 is provided between the integrated circuit device 75 and the glass substrate 77 to bond them together. The non-conductive film 79 has a part of glue thereof entering the spaces 74 to reinforce the bonding strength of the integrated circuit device 75 and the glass substrate 77.

In conclusion, the present invention provides the saliences with the spaces and the hollow portions to be the main character of technique. The fourth preferred embodiment is described hereunder to disclose the method of making the space 164 and the hollow portions 165, 166.

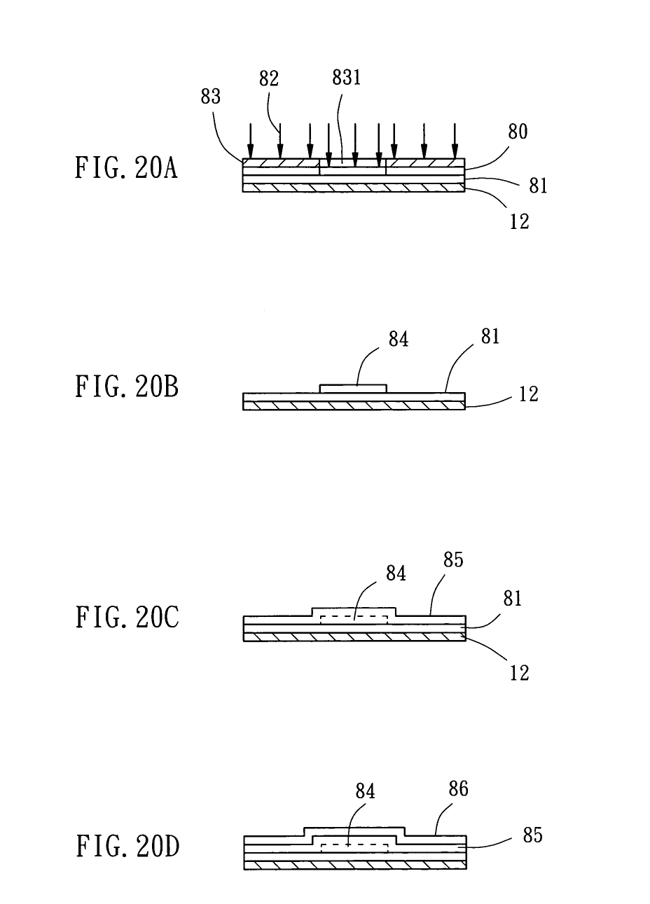

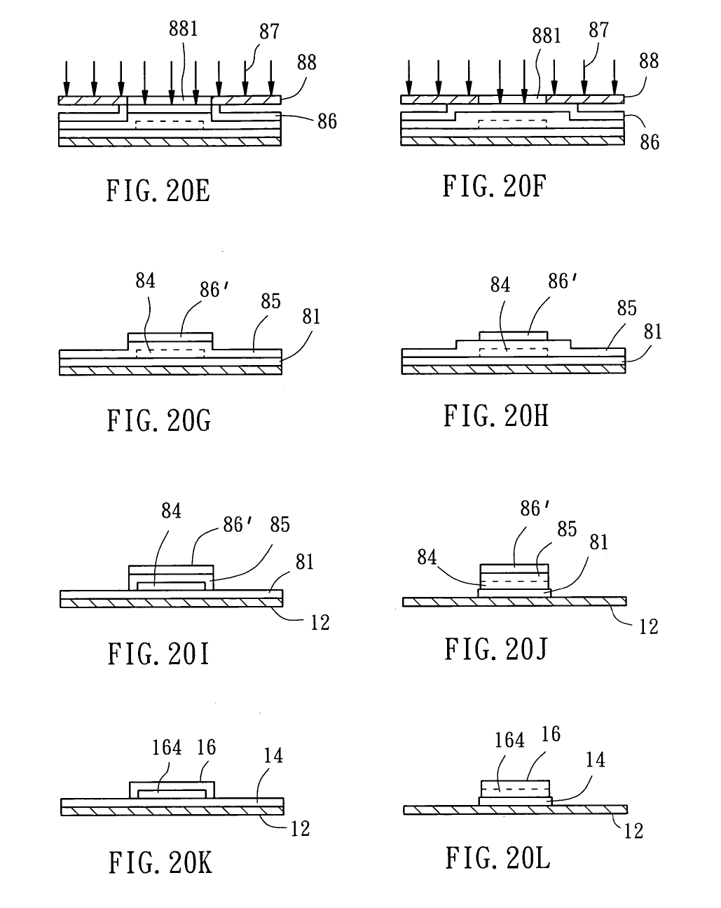

As shown in FIG. 20A, coating a negative photo resist 80 on a surface of a first metallic film 81. The first metallic film 81 is covered on the substrate 12 (glass substrate). Irradiating UV light on the negative photo resist 80 through a rectangular pervious region 831 of a mask 83 to produce a chemical reaction between the molecules of the negative photo resist 80 being irradiated.

FIG. 20B shows the mask 83 being removed and washing the negative photo resist 80 by a developing solution to remove the non-irradiated part and keep the irradiated part. The irradiated part of the negative photo resist 80 is defined as a support member 84.

FIG. 20C shows a second metallic film 85 covering the entire support member 84 and the first metallic film 81. The second metallic film 85 has convex portions aligned with the support member 84 respectively.

FIG. 20D shows coating a negative photo resist 86 again on a surface of the second metallic film 85.

FIG. 20E is shown along the X direction of FIG. 4, and FIG. 20F is shown along a Y direction of FIG. 4. The drawings show irradiating UV light 87 on the negative photo resist 86, and the negative photo resist 86 having a mask 88 thereon. It has to be mentioned that the mask 88 has a pervious region 881 with a length greater than that of the pervious region 831 of the mask 83, and with a width identical to that of the pervious region 831 of the mask 83.

FIG. 20G and FIG. 20H are shown along the X direction and the Y direction of FIG. 4 respectively. The drawings show the developing solution removing the non-irradiated part of the negative photo resist 86 and keeping the irradiated part of the photo resist 86′ thereof on the surface of the second metallic film 85 and right on the support member 84.

FIG. 20I and FIG. 20J are shown along the X direction and the Y direction of FIG. 4 respectively. The drawings show a dry etching or a wet etching is selected to remove predetermined portions of the first metallic film 81 and the second metallic film 85 in sequence, in which the portions are unshielded by the photo resist 86′. In other words, after the first etching process, the residual part of the second metallic film 85 forms the saliences 16. At this time, the support member 84 is covered by the second metallic film 85 but has two ends exposed. The second etching process makes the first metallic film 81 into a metallic conductive film having a predetermined pattern, and the metallic conductive film is the conductive media 14 of FIG. 4.

FIG. 20K and FIG. 20L are shown along the X direction and the Y direction of FIG. 4 respectively. The drawings show the negative photo resist 86′ and the support member 84 are treated by a solution to remove the support member 84. After the support member 84 is removed, it obtains the saliences 16 shown in FIG. 4, which has the space 164, the first hollow portion 165 and the second hollow portion 166.

In addition, the material made of the support member 84 may be any known photo resist material, and the material also may be epoxy, phenol formaldehyde resin, polyvinyl acetate emulsion (PAC) resin, acrylic resin, PI resin, halogen-containing resin, PAA resin, t-Boc (tert-butyloxycarbonyl), PHS resin, COMA resin, and cyclic olefin resin etc. These materials can be reacted with relative solutions to produce dissolving reaction in the process of removing the support member.

Although the invention has been explained in relation to its preferred embodiment, it is to be understood that many other possible modifications and variations can be made without departing from the spirit and scope of the invention as hereinafter claimed.

What is claimed is:

1. An electronic device with a conductive connection structure, comprising:
a substrate;
a plurality of conductive media disposed on a surface of the substrate; and
a plurality of saliences on surfaces of the conductive media respectively, each of which has a space therein and at least a hollow portion communicated with the space.

2. The electronic device with the conductive connection structure as defined in claim 1, wherein the substrate is an integrated circuit device with a plurality of traces therein.

3. The electronic device with the conductive connection structure as defined in claim 1, wherein the substrate is a glass substrate or a plastic substrate.

4. The electronic device with the conductive connection structure as defined in claim 1, wherein the conductive media are bump pads.

5. The electronic device with the conductive connection structure as defined in claim 1, wherein the conductive media are conductive films.

6. The electronic device with the conductive connection structure as defined in claim 1, wherein each of the saliences has a top portion and at least two lateral portions, and the lateral portions have two ends disposed at a surface of the conductive media and the top portion, and the space is formed within the top portion, the lateral portions and the corresponding conductive media.

7. The electronic device with the conductive connection structure as defined in claim 6, wherein the salience has two of the lateral portions at opposite sides thereof, which are connected to the top portion at ends thereof opposite to the conductive medium to form two of the hollow portions between the lateral portions respectively and to form the space within the top portion and the lateral portions.

8. The electronic device with the conductive connection structure as defined in claim 6, wherein the salience has three of the lateral portions and the hollow portion, which are a first lateral portion, a second lateral portion, and a third lateral portion having two ends connected to the first lateral portion and the second lateral portion, and the hollow portion are form between the first lateral portion and the second lateral portion opposite to the third lateral portion.

9. The electronic device with the conductive connection structure as defined in claim 6, wherein the top portion of the salience has a rough surface.

10. The electronic device with the conductive connection structure as defined in claim 1, wherein each of the saliences has a first inclining portion and a second inclining portion, each of which has touching portion at an end opposite to the conductive medium, and the space is formed within the first inclining portion, the second inclining portion, and the conductive media.

11. The electronic device with the conductive connection structure as defined in claim 1, wherein the saliences are made of a material selected from gold, silver, copper, nickel, aluminum, and alloy of those.

12. A conductive connection structure of an electronic apparatus, comprising:
a first electronic device having a plurality of first conductive media and conductive saliences, wherein the saliences are disposed at the first conductive media respectively, in each of which a space is formed and a hollow portion is provided communicated with the space;
a second electronic device having a plurality of second conductive media;
a conductive film having a plurality of conductive particles and a glue layer, which the conductive particles touch the saliences of the first electronic device and the second conductive media of the second electronic device, and the glue layer bonds the first electronic device and the second electronic device together.

13. The conductive connection structure of the electronic apparatus as defined in claim 12, wherein each of the saliences of the first electronic device has a top portion and at least two lateral portions, and the lateral portions have two ends disposed at a surface of the conductive medium and the top portion, and the space is formed within the top portion, the lateral portions and the corresponding conductive media.

14. The conductive connection structure of the electronic apparatus as defined in claim 12, wherein each of the saliences of the first electronic device has a first inclining portion and a second inclining portion, each of which has touching portion at an end opposite to the conductive medium, and the space is formed within the first inclining portion, the second inclining portion, and the conductive medium.

15. The conductive connection structure of the electronic apparatus as defined in claim 12, wherein the first electronic device is an integrated circuit device with a plurality of traces therein, and the first conductive media are disposed at a surface of the integrated circuit device and electrically connected to the traces, and the second electronic device has a substrate, on which the second conductive media are disposed.

16. The conductive connection structure of the electronic apparatus as defined in claim 12, wherein the first electronic device has a substrate, on which the first conductive media are disposed, and the second electronic device is an integrated circuit device with a plurality of traces therein, on which the second conductive media are disposed to be electrically connected to the traces.

17. A conductive connection structure of an electronic apparatus, comprising:
a first electronic device having a plurality of first conductive media and conductive saliences, which the saliences are disposed at the first conductive media respectively, in each of which a space is formed and a hollow portion is provided communicated with the space;
a second electronic device having a plurality of second conductive media to touch the saliences respectively;
a non-conductive film to bond the first electronic device and the second electronic device together.

18. The conductive connection structure of the electronic apparatus as defined in claim 17, wherein each of the saliences of the first electronic device has a top portion and at least two lateral portions, and the lateral portions have two ends disposed at a surface of the conductive medium and the top portion, and the space is formed within the top portion, the lateral portions and the corresponding conductive medium.

19. The conductive connection structure of the electronic apparatus as defined in claim 17, wherein each of the saliences of the first electronic device has a first inclining portion and a second inclining portion, each of which has touching portion at an end opposite to the conductive medium, and the space is formed within the first inclining portion, the second inclining portion, and the conductive medium.

20. The conductive connection structure of the electronic apparatus as defined in claim 17, wherein the first electronic device is an integrated circuit device with a plurality of traces therein, and the first conductive media are disposed at a surface of the integrated circuit device and electrically connected to the traces, and the second electronic device has a substrate, on which the second conductive media are disposed.

21. The conductive connection structure of the electronic apparatus as defined in claim 17, wherein the first electronic device has a substrate, on which the first conductive media are disposed, and the second electronic device is an integrated circuit device with a plurality of traces therein, on which the second conductive media are disposed to be electrically connected to the traces.
